(19) United States
(12) Patent Application Publication
(10) Pub. No.: US 2015/0180334 A1
(43) Pub. Date: Jun. 25, 2015

(54) DRIVING CIRCUIT FOR CHARGE PUMP CIRCUIT AND CHARGE PUMP SYSTEM INCLUDING THE SAME

(71) Applicant: SAMSUNG ELECTRO-MECHANICS CO., LTD., Suwon-Si (KR)

(72) Inventors: Moon Suk Jeong, Suwon-Si (KR); Byeong Hak Jo, Suwon-Si (KR); Yong Il Kwon, Suwon-Si (KR); Tah Joon Park, Suwon-Si (KR)

(73) Assignee: SAMSUNG ELECTRO-MECHANICS CO., LTD., Suwon-Si (KR)

(21) Appl. No.: 14/220,879

(22) Filed: Mar. 20, 2014

(30) Foreign Application Priority Data
Dec. 24, 2013 (KR) 10-2013-0162642

(51) Int. Cl. H02M 3/07; H03K 3/012

(52) U.S. Cl. CPC H02M 3/07; H03K 3/012

(57) ABSTRACT

There is provided a driving circuit for a charge pump circuit generating an output voltage by stepping-up an input voltage at least once, according to a clock signal. The driving circuit includes: an oscillator generating the clock signal; a comparison unit comparing the output voltage with a predetermined reference voltage; and a control unit generating a control signal to be provided to the oscillator, the control signal changing at least one of a frequency level and a duty level of the clock signal based on a comparison result from the comparison unit.

### CROSS-REFERENCE TO RELATED APPLICATION

This application claims the benefit of Korean Patent Application No. 10-2013-0162642 filed on Dec. 24, 2013, with the Korean Intellectual Property Office, the disclosure of which is incorporated herein by reference.

### BACKGROUND

The present disclosure relates to a driving circuit for a charge pump circuit, and a charge pump system including the same.

In general, a charge pump circuit is used for supplying voltages having a level higher than that of voltage from a power source.

A charge pump circuit stores voltage from a power source in capacitors by alternately applying a first clock signal having a specific frequency (on the level of several MHz) and a second clock signal having a phase difference of 180 degrees with respect to the first clock signal, to generate high voltages. More specifically, the charge pump circuit includes a plurality of transistors and stores the voltage from the power source in capacitors by switching the transistors on and off according to the first and second clock signals, to output high voltages.

Patent Document 1 below relates to an area-efficient charge pump circuit for devices having system-on-glass technology and discloses reducing levels of ripple voltages using a cross-coupling structure and generating a stabilized output voltage. However, Patent Document 1 is silent with regard to the problem in which a voltage output from a charge pump circuit is varied due to variations in a load current, i.e., variations in the resistance value of a load.

### RELATED ART DOCUMENT

(Patent Document 1) Korean Patent Laid-Open Publication No. 2005-0002785

### SUMMARY

An aspect of the present disclosure may provide a driving circuit for a charge pump circuit that regulates an output voltage from the charge pump circuit by changing at least one of a frequency level and a duty level of a clock signal provided to a step-up circuit, based on the output voltage.

According to an aspect of the present disclosure, a driving circuit for a charge pump circuit generating an output voltage by stepping-up an input voltage at least once, according to a clock signal may include: an oscillator generating the clock signal; a comparison unit comparing the output voltage with a predetermined reference voltage; and a control unit generating a control signal to be provided to the oscillator, the control signal changing at least one of a frequency level and a duty level of the clock signal based on a comparison result from the comparison unit.

The reference voltage may include a plurality of reference voltages, and the comparison unit includes a plurality of comparators, wherein each comparator among the plurality of comparators compares the output voltage with the plurality of reference voltages.

The plurality of reference voltages may include predetermined first and second reference voltages, and the comparison unit includes first and second comparators, wherein each comparator among the first and second comparators may compare the output voltage with the first and second reference voltages, respectively.

The first comparator may compare the first reference voltage with the output voltage; the second comparator may compare the second reference voltage with the output voltage, wherein a level of the first reference voltage is higher than a level of the second reference voltage.

The first comparator may be a first operational amplifier having an inverting input terminal to which the first reference voltage is applied and a non-inverting input terminal to which the output voltage is applied, and the second comparator may be a second operational amplifier having an inverting input terminal to which the second reference voltage is applied and a non-inverting input terminal to which the output voltage is applied.

The control unit may generate a control signal based on comparison results output from the plurality of comparators.

The control unit may generate the control signal for increasing at least one of the frequency level and the duty level of the clock signal in the case that the output voltage is higher than the first reference voltage, the control unit may generate the control signal for maintaining at least one of the frequency level and the duty level of the clock signal in the case that the output voltage is higher than the first reference voltage and lower than the second reference voltage, and the control unit may generate the control signal for decreasing at least one of the frequency level and the duty level of the clock signal in the case that the output voltage is lower than the second reference voltage.

The driving circuit may further include: a voltage detection unit detecting the output voltage so as to provide the detected output voltage to the comparison unit.

The voltage detection unit may divide the output voltage so as to provide the divided output voltage to the comparison unit.

According to another aspect of the present disclosure, a charge pump system may include: a charge pump circuit generating an output voltage by stepping-up an input voltage at least once, according to a clock signal; and a driving circuit comparing the output voltage with a predetermined reference voltage and changing at least one of a frequency level and a duty level of the clock signal, based on a comparison result, so as to regulate the output voltage.

The driving circuit may include: an oscillator generating the clock signal; a comparison unit comparing the output voltage with the reference voltage; and a control unit generating a control signal to be provided to the oscillator, the control signal changing at least one of the frequency level and the duty level of the clock signal based on the comparison result from the comparison unit.

The reference voltage may include a plurality of reference voltages, and the comparison unit includes a plurality of comparators, wherein each comparator among the plurality of comparators compares the output voltage with the plurality of reference voltages.

The plurality of reference voltages may include predetermined first and second reference voltages, and the comparison unit includes first and second comparators, wherein each comparator among the first and second comparators compares the output voltage with the first and second reference voltages, respectively.

The first comparator may compare the first reference voltage with the output voltage, the second comparator compares the second reference voltage with the output voltage, wherein a level of the first reference voltage is higher than a level of the second reference voltage.

The first comparator may be a first operational amplifier having an inverting input terminal to which the first reference voltage is applied and a non-inverting input terminal to which the output voltage is applied, and the second comparator may be a second operational amplifier having an inverting input terminal to which the second reference voltage is applied and a non-inverting input terminal to which the output voltage is applied.

The control unit may generate a control signal based on comparison results output from the plurality of comparators.

The control unit may generate the control signal for increasing at least one of the frequency level and the duty level of the clock signal in the case that the output voltage is higher than the first reference voltage, the control unit may generate the control signal for maintaining at least one of the frequency level and the duty level of the clock signal in the case that the output voltage is higher than the first reference voltage and lower than the second reference voltage, and the control unit may generate the control signal for decreasing at least one of the frequency level and the duty level of the clock signal in the case that the output voltage is higher than the second reference voltage.

The driving circuit may further include: a voltage detection unit detecting the output voltage so as to provide the detected output voltage to the comparison unit.

The voltage detection unit may divide the output voltage so as to provide the divided output voltage to the comparison unit.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram schematically illustrating a charge pump system according to an exemplary embodiment of the present disclosure;

FIG. 2 is a circuit diagram of a charge pump circuit, an element of a driving circuit for a charge pump system according to an exemplary embodiment of the present disclosure;

FIGS. 3 and 4 are circuit diagrams of a voltage detection unit, an element of a driving circuit for a charge pump circuit according to an exemplary embodiment of the present disclosure; and

FIG. 5 is a circuit diagram of the comparison unit, an element of the driving circuit for a charge pump circuit according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

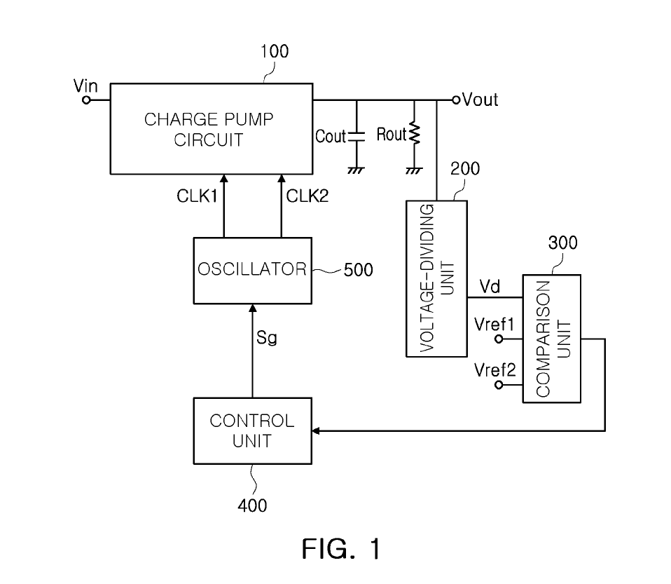

FIG. 1 is a block diagram schematically illustrating a charge pump system according to an exemplary embodiment of the present disclosure.

Referring to FIG. 1, the charge pump system according to the exemplary embodiment may include a charge pump circuit 100, a comparison unit 300, a control unit 400, an oscillator 500, as well as a voltage-dividing unit 200. The voltage-dividing unit 200, the comparison unit 300, the control unit 400 and the oscillator 500 may be implemented as a single integrated circuit (IC), serving as a driving circuit for driving the charge pump circuit.

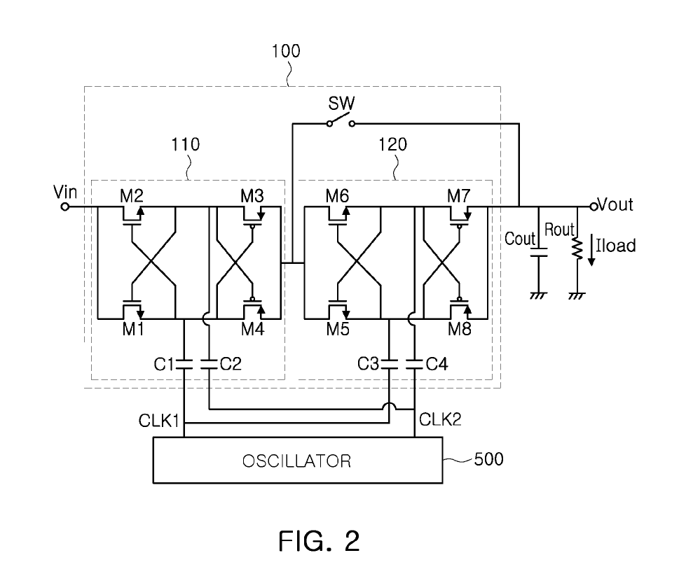

Hereinafter, the configuration of a charge pump circuit according to exemplary embodiments of the present disclosure will be described with reference to FIGS. 2 through 5.

FIG. 2 is a circuit diagram of a charge pump circuit, an element of a driving circuit for a charge pump system according to an exemplary embodiment of the present disclosure. Referring to FIG. 2, the charge pump circuit 100 may include a first step-up unit 110 and a second step-up unit 120.

Although the charge pump circuit 100 shown in FIG. 2 includes two step-up units 110 and 120, it is merely an example for convenience of illustration and it will be apparent that the charge pump circuit 100 according to the exemplary embodiment may include at least one step-up unit. In the case that the charge pump circuit 100 includes a plurality of step-up units, the charge pump circuit 100 may be used for a variety of purposes by controlling the switching operation of a switch SW so as to adjust the level of an output voltage Vₒᵤₜ depending on the magnitude of a load connected to an output terminal.

Hereinafter, for convenience of illustration, the charge pump circuit 100 will be described as including two step-up units 110 and 120.

A first step-up unit 110 may include n-type transistors M1 and M2, p-type transistors M3 and M4, and pumping capacitors C1 and C2. Similarly, a second step-up unit 120 may include n-type transistors M5 and M6, p-type transistors M7 and M8, and pumping capacitors C3 and C4.

In the first step-up unit 110, the transistors M1 and M4 and the capacitor C2 may configure a pumping circuit, and the transistors M2 and M3 and the capacitor C1 may configure another pumping circuit.

A connection node between the gates of the transistors M1 and M4 may be connected to one terminal of the capacitor C2, and the source of the transistor M2 and the drain of the transistor M3 are connected to the one terminal of the capacitor C2.

A connection node between the gates of the transistors M2 and M3 may be connected to one terminal of the capacitor C1, and the source of the transistor M1 and the drain of the transistor M4 are connected to the one terminal of the capacitor C1.

A connection node between the drains of the transistors M1 and M2 may be connected to an input terminal to which an input voltage Vᵢₙ is applied. A connection node between the sources of the transistors M3 and M4 may be connected to the second step-up unit 120. The other terminals of the capacitors C1 and C2 may receive clock signals CLK1 and CLK2 from the oscillator 500, respectively.

The clock signals CLK1 and CLK2 have a phase difference of 180 degrees with respect to each other, and have the same frequency. In the case that the clock signal CLK1 has a high level, the clock signal CLK2 has a low level, and vice versa.

In the case that the clock signal CLK1 has a high level while the clock signal CLK2 has a low level, the transistor M1 is turned off, the transistor M2 is turned on, the transistor M3 is turned off, and the transistor M4 is turned on. Accordingly, the input voltage Vᵢₙ applied to the input terminal is stored in the capacitor C2 through the transistor M2, and the voltage stored in the capacitor C1 is released to the second step-up unit 120.

In addition, in the case that the clock signal CLK1 has a low level while the clock signal CLK2 has a high level, the transistor M1 is turned on, the transistor M2 is turned off, the transistor M3 is turned on, and the transistor M4 is turned off. Accordingly, the input voltage Vᵢₙ applied to the input terminal is stored in the capacitor C1 through the transistor M1, and the voltage stored in the capacitor C2 is released to the second step-up unit 120.

The voltages released from the first step-up unit 110 to the second step-up unit 120 may be equal to voltages obtained by subtracting the voltage levels of the clock signals CLK1 and CLK2 from the voltages stored in the capacitors C1 and C2, respectively.

The operation of the second step-up unit 120 is similar to that of the first step-up unit 110. A voltage Vₒᵤₜ generated in the second step-up unit 120 when clock signals are applied to be stored in a capacitor Cout may be expressed by Mathematical expression 1 below:

Vₒᵤₜ=(1+2)*(Vin−VCLK) [Mathematical Expression 1]

where the number 2 denotes the number of step-up units, and the term VCLK denotes voltage level of clock signal.

As described above, the charge pump circuit 100 according to the exemplary embodiment may include a plurality of step-up units (N step-up units). In the case that the charge pump circuit 100 includes a plurality of step-up units (N step-up units), Mathematical Expression 1 may be expanded as Mathematical Expression 2:

Vₒᵤₜ=(1+N)*(Vin−VCLK) [Mathematical Expression 2]

The level of the output voltage Vₒᵤₜ generated in the charge pump circuit 100 may vary as a current I_{load} flowing through a load resistor Rout varies. According to the exemplary embodiment, in order to regulate the level of the output voltage Vₒᵤₜ, at least one of the frequency levels and duty levels of the clock signals CLK1 and CLK2 may be changed according to the level of the output voltage Vₒᵤₜ. This operation will be described below.

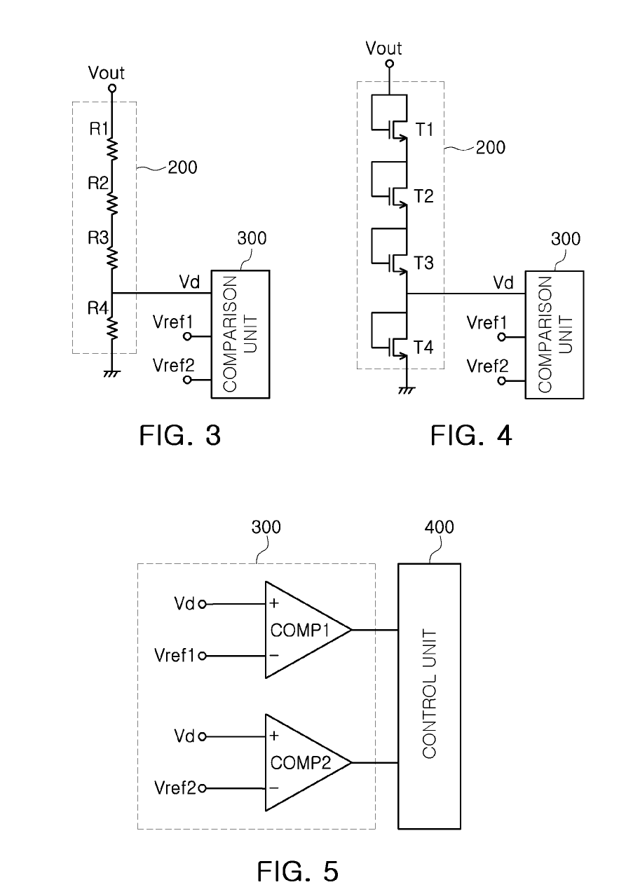

FIGS. 3 and 4 are circuit diagrams of a voltage detection unit, an element of a charge pump system according to an exemplary embodiment of the present disclosure. Although the voltage detection unit 200 may consist of one resistor for detecting the output voltage Vₒᵤₜ, the voltage detection unit 200 may consist of a plurality of resistors for detecting the output voltage Vₒᵤₜ by dividing the voltage detection unit 200 with the resistors, since the output voltage Vₒᵤₜ generated in the charge pump circuit 100 may have a high voltage level.

For example, the voltage detection unit 200 may consist of at least two resistors such that it may generate a divided voltage V_{d} that is determined by the ratio between resistance values of two resistors and may transmit the divided voltage V_{d} to the comparison unit 300.

The voltage detection unit 200 consists of four resistors R1, R2, R3 and R4 in FIG. 3, and the voltage detection unit 200 consists of four transistors T1, T2, T3 and T4 which are diode-connected in FIG. 4. However, these are merely examples and the number and type of the voltage detection unit 200 are not limited thereto.

FIG. 5 is a circuit diagram of the comparison unit, an element of the driving circuit for a charge pump circuit according to an exemplary embodiment of the present disclosure. The comparison unit 300 may compare the divided voltage V_{d} output from the voltage detection unit 200 with a predetermined reference voltage V_{ref} to output a comparison result.

The comparison unit 300 may include first and second comparators 310 and 320. The first comparator 310 may compare the divided voltage V_{d} with a first reference voltage V_{ref1} and the second comparator 320 may compare the divided voltage V_{d} with a second reference voltage V_{ref2}. Here, the voltage level of the first reference voltage V_{ref1} may be higher than the voltage level of the second reference voltage V_{ref2}.

The first and second comparators 310 and 320 may include operational amplifiers COMP1 and COMP2, respectively. The operational amplifier COMP1 may have a non-inverting input terminal to which the divided voltage V_{d} is input, and an inverting input terminal to which the first reference voltage V_{ref1} is input. The operational amplifier COMP2 may have a non-inverting input terminal to which the divided voltage V_{d} is input, and an inverting input terminal to which the second reference voltage V_{ref2} is input. In the case that the level of the divided voltage V_{d} is between that of the first reference voltage V_{ref1} and that of the second reference voltage V_{ref2}, the operational amplifier COMP1 may generate an output signal having a low level and the operational amplifier COMP2 may generate an output signal having a high level. In the case that the divided voltage V_{d} is higher than the first reference voltage V_{ref1} and the second reference voltage V_{ref2}, both of the operational amplifiers COMP1 and COMP2 may generate output signals having a high level. In addition, in the case that the divided voltage V_{d} is smaller than the first reference voltage V_{ref1} and the second reference voltage V_{ref2}, both of the operational amplifiers COMP1 and COMP2 may generate output signals having a low level.

Although the comparison unit 300 includes two comparators 310 and 320 in FIG. 5, the comparison unit 300 may include a plurality of comparators to compare the divided voltage with a plurality of reference voltages for determining the level of the divided voltage more precisely.

The control unit 400 may generate the control signal Sg based on the comparison result from the comparison unit 300 for controlling at least one of the frequency level and the duty level of a clock signal from the oscillator 500.

For example, in the case that the divided voltage V_{d} is smaller than the first reference voltage V_{ref1} and the second reference voltage V_{ref2}, a control signal

Sg for increasing the frequency level of the clock signal may be generated. In the case that the divided voltage V_{d} is greater than the first reference voltage V_{ref1} and the second reference voltage V_{ref2}, the control signal
Sg for decreasing the frequency level of the clock signal may be generated. In addition, in the case that the level of the divided voltage V_{d} is between that of the first reference voltage V_{ref1} and that of the second reference voltage V_{ref2}, it is determined that a desired condition is met, so that the control signal Sg for maintaining the frequency level of the clock signal may be generated.

For another example, in the case that the divided voltage V_{d} is smaller than the first reference voltage V_{ref1} and the second reference voltage V_{ref2}, a control signal Sg for increasing the duty level of the clock signal may be generated. In the case that the divided voltage V_{d} is greater than the first reference voltage V_{ref1} and the second reference voltage V_{ref2}, the control signal Sg for decreasing the duty level of the clock signal may be generated. In addition, in the case that the level of the divided voltage V_{d} is between that of the first reference voltage V_{ref1} and that of the second reference voltage V_{ref2}, it is determined that a desired condition is met, so that the control signal Sg for maintaining the duty level of the clock signal may be generated.

As set forth above, according to exemplary embodiment of the present disclosure, an output voltage from an step-up circuit may be regulated by changing at least one of a frequency level and a duty level of a clock signal provided to the step-up circuit based on the output voltage.

While exemplary embodiments have been shown and described above, it will be apparent to those skilled in the art that modifications and variations could be made without departing from the spirit and scope of the present disclosure as defined by the appended claims.

What is claimed is:

1. A driving circuit for a charge pump circuit generating an output voltage by stepping-up an input voltage at least once, according to a clock signal, the driving circuit comprising:
an oscillator generating the clock signal;
a comparison unit comparing the output voltage with a predetermined reference voltage; and
a control unit generating a control signal to be provided to the oscillator, the control signal changing at least one of a frequency level and a duty level of the clock signal based on a comparison result from the comparison unit.

2. The driving circuit of claim 1, wherein the reference voltage includes a plurality of reference voltages, and the comparison unit includes a plurality of comparators, wherein each comparator among the plurality of comparators compares the output voltage with the plurality of reference voltages.

3. The driving circuit of claim 2, wherein the plurality of reference voltages includes predetermined first and second reference voltages, and the comparison unit includes first and second comparators, wherein each comparator among the first and second comparators compares the output voltage with the first and second reference voltages, respectively.

4. The driving circuit of claim 3, wherein the first comparator compares the first reference voltage with the output voltage, the second comparator compares the second reference voltage with the output voltage, wherein a level of the first reference voltage is higher than a level of the second reference voltage.

5. The driving circuit of claim 4, wherein the first comparator is a first operational amplifier having an inverting input terminal to which the first reference voltage is applied and a non-inverting input terminal to which the output voltage is applied, and the second comparator is a second operational amplifier having an inverting input terminal to which the second reference voltage is applied and a non-inverting input terminal to which the output voltage is applied.

6. The driving circuit of claim 2, wherein the control unit generates a control signal based on comparison results output from the plurality of comparators.

7. The driving circuit of claim 4, wherein the control unit generates the control signal for increasing at least one of the frequency level and the duty level of the clock signal in the case that the output voltage is higher than the first reference voltage, the control unit generates the control signal for maintaining at least one of the frequency level and the duty level of the clock signal in the case that the output voltage is higher than the first reference voltage and lower than the second reference voltage, and the control unit generates the control signal for decreasing at least one of the frequency level and the duty level of the clock signal in the case that the output voltage is lower than the second reference voltage.

8. The driving circuit of claim 1, further comprising a voltage detection unit detecting the output voltage so as to provide the detected output voltage to the comparison unit.

9. The driving circuit of claim 8, wherein voltage detection unit divides the output voltage so as to provide the divided output voltage to the comparison unit.

10. A charge pump system, comprising:
a charge pump circuit generating an output voltage by stepping-up an input voltage at least once, according to a clock signal; and
a driving circuit comparing the output voltage with a predetermined reference voltage and changing at least one of a frequency level and a duty level of the clock signal, based on a comparison result, so as to regulate the output voltage.

11. The charge pump system of claim 10, wherein the driving circuit includes:
an oscillator generating the clock signal;
a comparison unit comparing the output voltage with the reference voltage; and
a control unit generating a control signal to be provided to the oscillator, the control signal changing at least one of the frequency level and the duty level of the clock signal based on the comparison result from the comparison unit.

12. The charge pump system of claim 11, wherein the reference voltage includes a plurality of reference voltages, and the comparison unit includes a plurality of comparators, wherein each comparator among the plurality of comparators compares the output voltage with the plurality of reference voltages.

13. The charge pump system of claim 12, wherein the plurality of reference voltages includes predetermined first and second reference voltages, and the comparison unit includes first and second comparators, wherein each comparator among the first and second comparators compares the output voltage with the first and second reference voltages, respectively.

14. The charge pump system of claim 13, wherein the first comparator compares the first reference voltage with the output voltage, the second comparator compares the second reference voltage with the output voltage, wherein a level of the first reference voltage is higher than a level of the second reference voltage.

15. The charge pump system of claim 14, wherein the first comparator is a first operational amplifier having an inverting input terminal to which the first reference voltage is applied and a non-inverting input terminal to which the output voltage is applied, and the second comparator is a second operational amplifier having an inverting input terminal to which the second reference voltage is applied and a non-inverting input terminal to which the output voltage is applied.

16. The charge pump system of claim 12, wherein the control unit generates a control signal based on comparison results output from the plurality of comparators.

17. The charge pump system of claim 14, wherein the control unit generates the control signal for increasing at least one of the frequency level and the duty level of the clock signal in the case that the output voltage is higher than the first reference voltage, the control unit generates the control signal for maintaining at least one of the frequency level and the duty level of the clock signal in the case that the output voltage is higher than the first reference voltage and lower than the second reference voltage, and the control unit generates the control signal for decreasing at least one of the frequency level and the duty level of the clock signal in the case that the output voltage is lower than the second reference voltage.

18. The charge pump system of claim 11, wherein the driving circuit further includes:
a voltage detection unit detecting the output voltage so as to provide the detected output voltage to the comparison unit.

19. The charge pump system of claim 18, wherein the voltage detection unit divides the output voltage so as to provide the divided output voltage to the comparison unit.
